(19) United States
(12) Patent Application Publication
(10) Pub. No.: US 2007/0241760 A1
(43) Pub. Date: Oct. 18, 2007

(54) Method for partial re-calibrating a network analyzer, and a network analyzer

(76) Inventor: Takashi Yamasaki, Hyogo (JP)

Correspondence Address: Paul D. Greeley, Esq.;Ohlandt, Greeley, Ruggiero & Perle, L.L.P., One Landmark Square, 10th Floor, Stamford, CT, 06901-2682, US

(21) Appl. No.: 11/784,990

(22) Filed: Apr. 10, 2007

(30) Foreign Application Priority Data
Apr. 17, 2006 (JP) 2006-113696

(51) Int. Cl. G01R 35/00

(52) U.S. Cl. 324/601

(57) ABSTRACT

A calibrated network analyzer is re-calibrated by measuring a circuit parameter of a standard device, specifying the type of error coefficient relating to this measured circuit parameter, and calculating an error coefficient of this specified type using this measured circuit parameter. Moreover, of the circuit parameters necessary for this calculation, a circuit parameter other than this measured circuit parameter is reproduced using the theoretical value of this circuit parameter and the standard coefficient obtained by this calibration.

### BACKGROUND

1. Field of the Disclosure

The present disclosure pertains to network analyzer calibration technology, and relates particularly to re-calibration technology.

2. Discussion of the Background Art

Network analyzers, which are devices for measuring the circuit parameters that represent the network properties of a device under test, and measurement systems comprising network analyzers are calibrated before a device under test is measured, so that the systematic error coefficient can be eliminated from the measurement value. In general, response calibration, one-port calibration, TRL calibration and full N-port calibration are methods of network analyzer calibration. Full N-port calibration takes into consideration all of the primary factors of a systematic error coefficient and is therefore capable of obtaining the most precise result. N is the number of measurement ports of the subject of calibration.

Conventional full N-port calibration is performed using an open standard device, a short standard device, a load standard device, or a thru standard device (Refer to JP Unexamined Patent Publication (Kokai) 08-043463 (page 2)). These standard devices are connected to the respective measurement port of a calibration subject or connected between the measurement ports during the calibration step and a circuit parameter is measured for each connection. In the past, all calibration steps were performed again from the beginning not only for full N-port calibration, but also for re-calibration that was performed for reasons that included calibration errors and modification of the calibration kit. Incidentally, the total number of times a standard device is attached and disconnected during all of the calibration steps in the case of full 4-port calibration is 48 times (=4×3×2+₄C₂×2×2). Moreover, the number of measurement steps in all of the steps of the same calibration is 18 steps (4×3+₄C₂). Completely re-performing each of these connection/disconnection procedures and measurement procedures requires considerable time and labor.

Therefore, a calibration method has been proposed such that corrected measurement values are displayed during the calibration procedure and the operator can re-measure only the desired parameters (refer to JP Unexamined Patent Publication (Kokai) 2003-294820 (page 4, FIG. 5)). See also JP Unexamined Patent Publication (Kokai) 2005-091194 (page 4, FIG. 5)

By means of the previously proposed method, all of the measurements of a standard device are retained until the calibration procedure is completed in order to make re-measurement possible. Consequently, when there is an increase in the number of measurement ports or the number of measurement points, there is an increase in the number of measurements that need to be retained and a large-capacity memory therefore becomes necessary. Moreover, by means of this previously proposed method, when the calibration procedure is completed, all of the measurement values of the standard device that were retained are discarded. Consequently, once calibration has been completed, re-calibration requires that all steps be performed again from the beginning as in the case of the conventional calibration. A large-capacity memory eventually becomes necessary if the measurements of a standard device continue to be retained.

### SUMMARY OF THE DISCLOSURE

An object of the present disclosure is to provide a technology with which a re-calibration that is more efficient than in the past is possible without retaining measurement values. The present disclosure provides a novel re-calibrating method and a network analyzer necessary for executing this method. In essence, the first subject of the invention is a method for re-calibrating a calibrated network analyzer, said re-calibrating method comprising a step wherein a circuit parameter of a standard device is measured; a step wherein the type of error coefficient relating to this measured circuit parameter is specified; and a step wherein an error coefficient of this specified type is calculated using this measured circuit parameter.

The second subject of the invention is the method according to the first subject of the invention, further characterized in that it comprises a step wherein, of the circuit parameters necessary for this calculation, a circuit parameter other than this measured circuit parameter is reproduced using the theoretical value of this circuit parameter and the error coefficient obtained by this calibration.

The third subject of the invention is the method according to the first or second subject of the invention, further characterized in that it comprises a step wherein the value of the error coefficient obtained by this calculation is written over the error coefficient obtained by this calibration.

The fourth subject of the invention is a network analyzer, wherein a measurement value is corrected based on an error coefficient obtained by calibration, and also, of the error coefficients obtained by this calibration, an error coefficient that has been re-calculated using the measurement values of a standard device obtained after this calibration.

The fifth subject of the invention is the network analyzer according to the fourth subject of the invention, further characterized in that, of the measurement values necessary for this re-calculation, a measurement value other than the measurement value obtained after this calibration is reproduced using the theoretical value corresponding to this measurement value and the error coefficient obtained by this calibration.

The sixth subject of the invention is the network analyzer according to the fourth or fifth subject of the invention, further characterized in that, when the value of the error coefficient obtained by this re-calculation is written over the error coefficient obtained by this calibration, the measurement value is corrected based on this written-over error coefficient.

By means of the present disclosure, a memory for retaining the measurements during calibration becomes unnecessary. By means of the present disclosure, it is possible to re-access only predetermined standard device measurement values for re-calibration once calibration has been completed, and it is not necessary to perform again from the beginning all of the standard device connection/disconnection procedures and measurement procedures. Furthermore, the present disclosure simplifies calibration using a standard device belonging to two or more different calibration kits. For example, it is possible to calibrate a network analyzer using an electronic calibration kit and then to re-calibrate the same network analyzer using the thru standard device of another calibration kit.

### BRIEF DESCRIPTION OF THE DRAWINGS

FIG. 1 is a block drawing showing the structure of network analyzer 10, which is the first embodiment of the present disclosure.

FIG. 2 is a flow chart showing the re-calibration procedure for network analyzer 10.

FIG. 3 is the signal flow of a 1-port error model.

FIG. 4 is a drawing showing the error coefficient values stored in memory 400.

### DETAILED DESCRIPTION OF THE PREFERRED EMBODIMENT

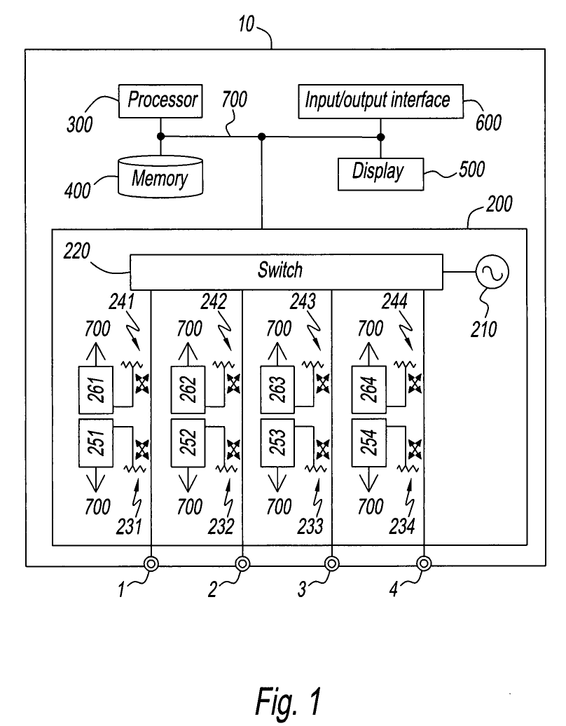

Embodiments of the present disclosure will now be described while referring to the attached drawings. The embodiment of the present disclosure is a network analyzer 10. First, the structure of network analyzer 10 will be described and then the method for re-calibrating network analyzer 10 will be described. Refer to FIG. 1. FIG. 1 is a block diagram showing the general structure of network analyzer 10.

Network analyzer 10 comprises measurement ports 1, 2, 3, and 4 for connecting a device under test (not shown), a measurement part 200, a processor 300, a memory 400, a display 500, and an input/output interface 600.

Measurement part 200 is connected to measurement ports 1, 2, 3, and 4. Measurement part 200 has a signal source 210 and a switch 220. Signal source 210 is a device for generating measurement signals (stimulus signals) for application to a device under test (not shown). Switch 220 is the device that selects any of measurement ports 1, 2, 3, and 4 and electrically connects the selected measurement port to the output terminal of signal source 210. The measurement ports that have not been selected by switch 220 are terminated to prevent reflection. Moreover, measurement part 200 comprises directional couplers 231, 232, 233, 234, 241, 242, 243, and 244, and reference receivers 251, 252, 253, 254, 261, 262, 263, and 264. The reference receivers are simply referred to hereafter as receivers.

Directional coupler 231 is disposed between switch 220 and measurement port 1 and is a device that extracts some of the signals that are directed from measurement port 1 toward switch 220. Receiver 251 is connected to directional coupler 231 and is a device for measuring the input signal power at measurement port 1. Directional coupler 241 is disposed between switch 220 and measurement port 1 and is a device for extracting some of the signals directed from switch 220 toward measurement port 1. Receiver 261 is connected to directional coupler 241 and is a device for measuring the input signal power at measurement port 1. It should be noted that the output signals at the measurement ports are the signals that will be input from outside of network analyzer 10 at the measurement port in question to network analyzer 10. Moreover, the output signals at the measurement ports are the signals that will be output from network analyzer 10 to outside of network analyzer 10 at the measurement port in question.

Directional coupler 232 is disposed between switch 220 and measurement port 2 and is a device that extracts some of the signals that are directed from measurement port 2 toward switch 220. Receiver 252 is connected to directional coupler 232 and is a device for measuring the input signal power at measurement port 2. Directional coupler 242 is disposed between switch 220 and measurement port 2 and is a device for extracting some of the signals directed from switch 220 toward measurement port 2. Receiver 262 is connected to directional coupler 242 and is a device for measuring the output signal power at measurement port 2.

Directional coupler 233 is disposed between switch 220 and measurement port 3 and is a device that extracts some of the signals that are directed from measurement port 3 toward switch 220. Receiver 253 is connected to directional coupler 233 and is a device for measuring the input signal power at measurement port 3. Directional coupler 243 is disposed between switch 220 and measurement port 3 and is a device for extracting some of the signals directed from switch 220 toward measurement port 3. Receiver 263 is connected to directional coupler 243 and is a device for measuring the output signal power at measurement port 3.

Directional coupler 234 is disposed between switch 220 and measurement port 4 and is a device that extracts some of the signals that are directed from measurement port 4 toward switch 220. Receiver 254 is connected to directional coupler 234 and is a device for measuring the input signal power at measurement port 4. Directional coupler 244 is disposed between switch 220 and measurement port 4 and is a device for extracting some of the signals directed from switch 220 toward measurement port 4. Receiver 264 is connected to directional coupler 244 and is a device for measuring the output signal power at measurement port 4.

Processor 300 is a device for controlling each of the structural elements of network analyzer 10 and processing each operation by execution of programs. Processor 300 comprises, for instance, a CPU, DSP, RISC or ASIC or FPGA, wherein any of these serve as the core. Memory 400 is a device for storing program codes and data. Memory 400 comprises, for instance, a semiconductor memory such as a DRAM or a hard disk drive. Display part 500 has a display screen, which is not illustrated, and is a device for presenting various types of data, such as measurement results and settings data, to the operator of network analyzer 10 through this display screen. Input interface 600 is a device by means of which data are exchanged between network analyzer 10 and parts external to network analyzer 10. Input/output interface 600 is, for instance, a keyboard, mouse, vernier knob, button, USB interface, LAN interface, or PCMCIA interface. It can also be a removable medium drive such as a floptical disk drive or a CD/DVD drive. The above-mentioned is a description of the structure of network analyzer 10.

Next, the re-calibrating procedure of network analyzer 10 will be described. This embodiment describes the procedure whereby once network analyzer 10 has been subjected to a full 4-port calibration, network analyzer 10 is partially re-calibrated.

First, a calibration of some sort has been performed at least once as a prerequisite to re-calibration. By means of the present embodiment, a full 4-port calibration has been performed prior to re-calibration; therefore, a directional error coefficient Ed, an isolation error coefficient Ex, a source-match error coefficient Es, a load match error coefficient El, a reflection tracking error coefficient Er, and a transmission tracking error coefficient Et are found. It goes without saying that these error coefficients are found by calculation from the S-parameter measurement values of each standard device. These error coefficients are used as coefficients for correcting measurement values, and can also be referred to simply as errors or error terms, calibration coefficients, or correction coefficients. Directional error coefficient Ed, source-match error coefficient Es, and reflection tracking error coefficient Er are present at each stimulus port. Isolation error coefficient Ex, load match error coefficient El, and transmission tracking error coefficient Et are present for each combination of stimulus port and response port. In short, overall there are 48 types of error coefficients. The stimulus port is the measurement port that outputs the measurement signals. Moreover, the response port is the measurement port that receives the measurement signals. The error coefficient is found for each measurement frequency point and is stored in memory 400 as a numerical array for each type of error coefficient. The S-parameter measurement values stored inside memory 400 in order to find the error coefficients are all discarded when the calibration is over so that there are none remaining.

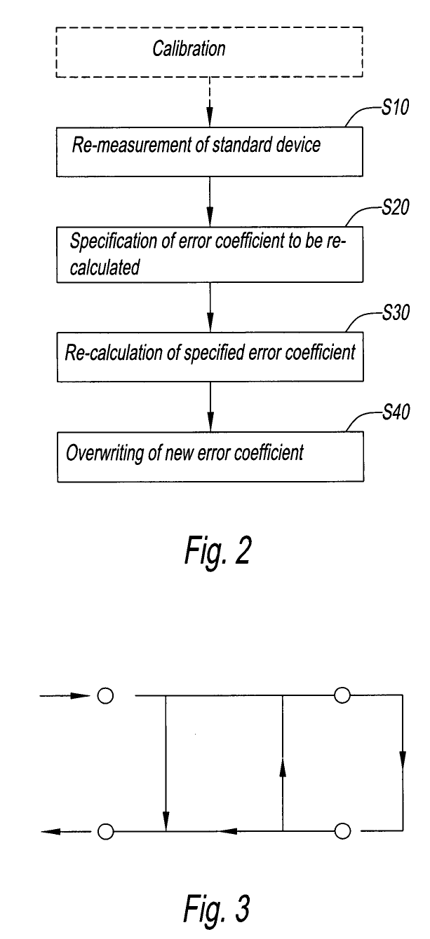

The procedure for re-calibrating the network analyzer 10 in such a state will be described while referring to FIGS. 1 and 2. FIG. 2 is a flow chart showing the re-calibrating procedure of a full 4-port calibration. Each of the following steps is performed by processor 300 itself, or by one or more structural elements inside network analyzer 10 controlled by processor 300. Processor 300 performs or controls the above-mentioned steps by executing programs stored in memory 400.

First, a predetermined S parameter relating to a predetermined standard device is measured. The S parameter of the measurement subject can be an S parameter from which measurement has been omitted by technology cited in JP Unexamined Patent Publication (Kokai) 8-62316, an S parameter relating to the error coefficient that presumably requires re-calibration, and the like. The S parameter of these measurement subjects is determined by the operator of network analyzer 10 based on measurement results displayed on display 500. In this case, the operator of network analyzer 10 indicates or selects the S parameter of the measurement subject through input/output interface 600. Measurement part 200 measures the S parameter at each measurement frequency point and the measurement results are stored in memory 400 in the form of a numerical array.

Next, the type of error coefficient that is to be re-calculated is specified in step S20. The type of error coefficient to be calculated is specified while referring to Table 1. Table 1 was created based on formulas 1 through 6 below, and is stored in memory 400 as data in table format. It should be noted that persons skilled in the art can easily perform the same processing using conditional statements in the program rather than referring to data in table format.

TABLE 1
Correlation coefficients of re-calculation subject

| | | Standard device connected to measurement port | | | | | |
|---|---|---|---|---|---|---|---|
| | | | Open | Short | Load | Thru | |
| Measurement | Reflection | S₁₁ | Es₁, Ed₁, Er₁ | Es₁, Ed₁, Er₁ | Es₁, Ed₁, Er₁ | Port 1–2 | El₂₁ |
| parameter | parameter | | El₂₁, El₃₁, El₄₁ | El₂₁, El₃₁, El₄₁ | El₂₁, El₃₁, El₄₁ | Port 1–3 | El₃₁ |
| | | | Et_{21,} Et_{31,} Et₄₁ | Et_{21,} Et_{31,} Et₄₁ | Et_{21,} Et_{31,} Et₄₁ | Port 1–4 | El₄₁ |
| | | S₂₂ | Es₂, Ed₂, Er₂ | Es₂, Ed₂, Er₂ | Es₂, Ed₂, Er₂ | Port 1–2 | El₁₂ |
| | | | El₁₂, El₃₂, El₄₂ | El₁₂, El₃₂, El₄₂ | El₁₂, El₃₂, El₄₂ | Port 2–3 | El₃₂ |
| | | | Et_{12,} Et_{32,} Et₄₂ | Et_{12,} Et_{32,} Et₄₂ | Et_{12,} Et_{32,} Et₄₂ | Port 2–4 | El₄₂ |
| | | S₃₃ | Es₃, Ed₃, Er₃ | Es₃, Ed₃, Er₃ | Es₃, Ed₃, Er₃ | Port 1–3 | El₁₃ |
| | | | El₁₃, El₂₃, El₄₃ | El₁₃, El₂₃, El₄₃ | El₁₃, El₂₃, El₄₃ | Port 2–3 | El₂₃ |
| | | | Et_{13,} Et_{23,} Et₃₂ | Et_{13,} Et_{23,} Et₃₂ | Et_{13,} Et_{23,} Et₃₂ | Port 3–4 | El₄₃ |
| | | S₄₄ | Es₄, Ed₄, Er₄ | Es₄, Ed₄, Er₄ | Es₄, Ed₄, Er₄ | Port 1–4 | El₁₄ |
| | | | El₁₄, El₂₄, El₃₄ | El₁₄, El₂₄, El₃₄ | El₁₄, El₂₄, El₃₄ | Port 2–4 | El₂₄ |
| | | | Et_{14,} Et_{24,} Et₃₄ | Et_{14,} Et_{24,} Et₃₄ | Et_{14,} Et_{24,} Et₃₄ | Port 3–4 | El₃₄ |

| | | |
|---|---|---|
| Transmission | S₁₂ | Et₁₂ |
| parameter | S₂₁ | Et₂₁ |
| | S₁₃ | Et₁₃ |
| | S₃₁ | Et₃₁ |
| | S₁₄ | Et₁₄ |
| | S₄₁ | Et₄₁ |
| | S₂₃ | Et₂₃ |
| | S₃₂ | Et₃₂ |
| | S₂₄ | Et₂₄ |
| | S₄₂ | Et₄₂ |
| | S₃₄ | Et₃₄ |
| | S₄₃ | Et₄₃ |

| | | |
|---|---|---|
| Isolation | S₁₂ | Ex₁₂, Et₁₂ |
| parameter | S₂₁ | Ex₂₁, Et₂₁ |
| | S₁₃ | Ex₁₃, Et₁₃ |
| | S₃₁ | Ex₃₁, Et₃₁ |
| | S₁₄ | Ex₁₄, Et₁₄ |
| | S₄₁ | Ex₄₁, Et₄₁ |
| | S₂₃ | Ex₂₃, Et₂₃ |
| | S₃₂ | Ex₃₂, Et₃₂ |
| | S₂₄ | Ex₂₄, Et₂₄ |
| | S₄₂ | Ex₄₂, Et₄₂ |
| | S₃₄ | Ex₃₄, Et₃₄ |
| | S₄₃ | Ex₄₃, Et₄₃ |

The S parameters and error coefficients shown in Table 1 are those known for full 4-port calibration, but as a precaution, they are described briefly below. The S parameter subscript on the right represents the stimulus port number. The S parameter subscript on the left represents the response port number. Error coefficients Edᵢ, Esᵢ, and Erᵢ are the error coefficients relating to measurement port i. Error coefficients Exⱼᵢ, Elⱼᵢ, and Etⱼᵢ are the error coefficients relating to a pair of measurement ports i and j. It should be noted that the i of the measurement port is the number of the stimulus port. Moreover, the j of the measurement port is the number of the response port. The number of the response port of error coefficients Edᵢ, Esᵢ, and Erᵢ is the same as the number of the stimulus port.

Table 1 shows the combination of the type of standard device connected to the measurement port and the type of S parameter that will be measured, and the relationship with the error coefficient. An example of Table 1 will now be given. According to Table 1, when S₁₁ is measured with an open standard device connected to measurement port 1, S₁₁Mo, which is the measurement result, clearly has an effect on error coefficients Es₁, Ed₁, Er₁, El₂₁, El₃₁, El₄₁, Et₂₁, Et₃₁, and Et₄₁. In other words, S₁₁Mo is used to find these error coefficients. Consequently, when S₁₁ is measured with the open standard device connected to measurement port 1, error coefficients Es₁, Ed₁, Er₁, El₂₁, El₃₁, El₄₁, Et₂₁, Et₃₁, and Et₄₁ become the subjects of re-calculation. It should be noted that when reflection is measured, the number of the measurement port connected to the open, short, or load standard device is specified by the subscript of the S parameter; therefore, it is not represented in Table 1.

Moreover, according to Table 1, when S₁₁ is measured with the thru standard device connected to port 1, any of error coefficients El₂₁, El₃₁ and El₄₁ becomes the subject of re-calculation. Whether it is error coefficient El₂₁, El₃₁ or El₄₁ is determined by the pair of measurement ports to which the thru standard device is connected. The pair of measurement ports is displayed in the row for thru standard device in Table 1. For example, when S₁₁ is measured with the thru standard device connected between measurement port 1 and measurement port 4, error coefficient El₄₁ becomes the subject of re-calculation.

Furthermore, according to Table 1, when S₂₁ is measured with the thru standard device connected between measurement port 1 and measurement port 2, error coefficient Et₂₁ becomes the subject of recalculation. It should be noted that the number of the measurement port to which the thru standard device is connected is specified by the subscript of the S parameter; therefore it is not represented in Table 1.

In addition, according to Table 1, when S₂₃ is measured with the isolation standard device connected to all of the measurement ports of the calibration subject, error coefficients Ex₂₃ and Et₂₃ become the subject of recalculation. The isolation standard device is the device that individually subjects each of the measurement ports of the calibration subject to reflection-free termination, and is actually replaced by the load standard device to which all of the measurement ports of the calibration subject are simultaneously connected. The “isolation measurement” in Table 1 is transmission measurement with the isolation standard device connected.

Next, in step S30, the error coefficient of the type specified by step S20 is re-calculated. Calculation of each of the error coefficients is performed by processor 300 using the formulas 1 through 6 below. The measurement values of the short standard device, the open standard device, and the load standard device at measurement port i become SᵢᵢMs, SᵢᵢMo, and SᵢᵢM1. The theoretical values corresponding to these measurement values are SᵢᵢAs, SᵢᵢAo, and SᵢᵢA1. The theoretical values are obtained from the definitions of the calibration kit or from the property values of an ideal standard device. In the case of an ideal thru standard device for instance SᵢᵢAt=SⱼⱼAt=0, SᵢⱼAt=SⱼᵢAt=1. The alphabetical letters following the “M” and “A” in the S-parameter symbols represent the type of standard device connected to measurement port i. Specifically, “s” represents the short standard device, “o” represents the open standard device, and “1” represents the load standard device. The crosstalk from measurement port i to measurement port j is SⱼᵢMᵢₛₒₗ. Furthermore, the measurement values of the thru standard device connected between measurement port i and measurement port j becomes SᵢᵢMt, SᵢⱼMt, SⱼᵢMt, and SⱼⱼMt. The theoretical values corresponding to these measurements are SᵢᵢAt, SᵢⱼAt, SⱼᵢAt, SⱼⱼAt. i and j are the number of the response port and the number of the stimulus port, respectively, as previously mentioned.

$$\begin{matrix}{Es}_{i} = \frac{\begin{matrix}{S}_{ii} Mo ( {S}_{ii} Al - {S}_{ii} As ) + \\ {S}_{ii} Ms ( {S}_{ii} Ao - {S}_{ii} Al ) + \\ {S}_{ii} Ml ( {S}_{ii} As - {S}_{ii} Ao )\end{matrix}}{det} & ( Formula 1 ) \\ {Ed}_{i} = \frac{\begin{matrix}{S}_{ii} Mo \cdot {S}_{ii} Ao ( {S}_{ii} Ms \cdot {S}_{ii} Al - {S}_{ii} As \cdot {S}_{ii} Ml ) + \\ {S}_{ii} Ms \cdot {S}_{ii} As ( {S}_{ii} Ml \cdot {S}_{ii} Ao - {S}_{ii} Al \cdot {S}_{ii} Mo ) + \\ {S}_{ii} Ml \cdot {S}_{ii} Al ( {S}_{ii} Mo \cdot {S}_{ii} As - {S}_{ii} Ao \cdot {S}_{ii} Ms )\end{matrix}}{det} & ( Formula 2 ) \\ {Er}_{i} = {Es}_{i} \cdot {Ed}_{i} + \frac{\begin{matrix}{S}_{ii} Mo \cdot {S}_{ii} Ao ( {S}_{ii} Ml - {S}_{ii} Ms ) + \\ {S}_{ii} Ms \cdot {S}_{ii} As ( {S}_{ii} Mo - {S}_{ii} Ml ) + \\ {S}_{ii} Ml \cdot {S}_{ii} Al ( {S}_{ii} Ms - {S}_{ii} Mo )\end{matrix}}{det} \\ Here , & ( Formula 3 ) \\ det = {S}_{ii} Mo \cdot {S}_{ii} Ao ( {S}_{ii} Al - {S}_{ii} As ) + {S}_{ii} Ms \cdot {S}_{ii} As ( {S}_{ii} Ao - {S}_{ii} Al ) + {S}_{ii} Ml \cdot {S}_{ii} Al ( {S}_{ii} As - {S}_{ii} Ao ) \\ {Ex}_{ji} = {S}_{ji} {M}_{isol} & ( Formula 4 ) \\ {El}_{ji} = \frac{1}{\frac{{S}_{ji} At \cdot {S}_{ij} At}{\frac{1}{\frac{{Er}_{i}}{{S}_{ii} M t - {Ed}_{i}} + {Es}_{i}} - {S}_{ii} At} + {S}_{ij} At} & ( Formula 5 ) \\ {Et}_{ji} = ( {S}_{ji} M t - {Ex}_{ji} ) \frac{1 - \frac{{S}_{ji} At \cdot {S}_{ij} At \cdot {El}_{ji} \cdot {Es}_{i}}{1 - {S}_{ii} At \cdot {Es}_{i}} - {S}_{jj} At \cdot {El}_{ji}}{{S}_{ji} At + \frac{{S}_{ji} At \cdot {Es}_{i} \cdot {S}_{ii} At}{1 - {S}_{ii} At \cdot {Es}_{i}}} & ( Formula 6 )\end{matrix}$$

When formula 5 is substituted for formula 6, El can be removed from the calculation of Et. In short, El is not needed to calculate Et.

In step 10, when the open standard device is connected to the measurement port 1 and only S₁₁ is re-measured, error coefficients Es₁, Ed₁, Er₁, El₂₁, El₃₁, El₄₁, Et₂₁, Et₃₁, and Et₄₁ are re-calculated. According to Table 2, measurement values of standard devices other than the open standard device are necessary for the calculation of error coefficients Es₁, Ed₁, Er₁, El₂₁, El₃₁, El₄₁, Et₂₁, Et₃₁, and Et₄₁. It should be noted that as with Table 1, Table 2 was created based on formulas 1 through 6.

TABLE 2
Standard devices necessary for calculation of error
coefficients and error coefficients

| Type of error | | Type of error | |
|---|---|---|---|
| coefficient of | Type of standard | coefficient | Type of error |
| calculation | device necessary for | necessary for | coefficient affected |
| subject | calculation | calculation | by calculation |
| Es | Open, short, load | None | El, Et |
| Ed | Open, short, load | None | El, Et |
| Er | Open, short, load | None | E1, Et |
| Ex | Isolation (load | None | Et |
| | connected to all | | |
| | measurement ports | | |
| | of calibration | | |
| | subject) | | |
| El | Thru | Es, Ed, Er | None |
| Et | Thru | Es, Ed, Er, Ex | None |

In this step (S30), of the measurement values of the standard devices necessary for calculation of the error coefficient, the values not measured in step 10 are reproduced by calculation based on the theoretical value of the standard device and the error coefficient obtained by pre-calibration. The error coefficient is a function of the theoretical value and the measurement value, and the measurement value can therefore be represented as the inverse function of the theoretical value and the error coefficient. In this step, processor 300 finds the hypothetical measurement value from the theoretical value and the error coefficient using the inverse function in question. Thereafter, a “v” is added to the end of the hypothetical measurement value obtained by calculation in order to differentiate it from the values obtained by actual measurement. Moreover, “old” is added to the end of an error coefficient obtained by pre-calibration in order to differentiate it from the value of an error coefficient newly obtained by re-calculation. On the other hand, “new” is added to the end of the value of an error coefficient newly obtained by the calculation.

First, when formulas 5 and 6 are modified, formulas 7 and 8 are obtained whereby hypothetical measurement values SᵢᵢMtv and SⱼᵢMtv for the thru standard device are obtained.

$$\begin{matrix}{S}_{ii} Mtv = \frac{{Er}_{i} old}{\frac{1}{\frac{{S}_{ji} At \cdot {S}_{ij} At}{\frac{1}{{El}_{ji} old} - {S}_{jj} At} + {S}_{li} At} - {Es}_{i} old} + {Ed}_{i} old & ( Formula 7 ) \\ {S}_{ji} Mtv = \frac{{Et}_{ji} old ( {S}_{ji} At + \frac{{S}_{ji} At \cdot {Es}_{i} old \cdot {S}_{ii} At}{1 - {S}_{ii} At \cdot {Es}_{i} old} )}{1 - \frac{{S}_{ji} At \cdot {S}_{ij} At \cdot {El}_{ji} old \cdot {Es}_{i} old}{1 - {S}_{ii} At \cdot {Es}_{i} old} - {S}_{jj} At \cdot {El}_{ji} old} + {Ex}_{ji} old & ( Formula 8 )\end{matrix}$$

Next, hypothetical measurement values SᵢᵢMov, SᵢᵢMsv, and SᵢᵢMlv of the open, short, and load standard devices are found. The formulas for finding these hypothetical values can be derived from the signal flow of the 1-port error model shown in FIG. 3.

$$\begin{matrix}{S}_{ii} Mov = \frac{{S}_{ii} Ao}{1 - {S}_{ii} Ao \cdot {Es}_{i} old} {Er}_{i} old + {Ed}_{i} old & ( Formula 9 ) \\ {S}_{ii} Msv = \frac{{S}_{ii} As}{1 - {S}_{ii} As \cdot {Es}_{i} old} {Er}_{i} old + {Ed}_{i} old & ( Formula 10 ) \\ {S}_{ii} Mlv = \frac{{S}_{ii} Al}{1 - {S}_{ii} Al \cdot {Es}_{i} old} {Er}_{i} old + {Ed}_{i} old & ( Formula 11 )\end{matrix}$$

When the above-mentioned example is cited, when the open standard device is connected to measurement port 1 and only S₁₁ is re-measured in step 10, error coefficients Es₁, Ed₁, Er₁, El₂₁, El₃₁, El₄₁, Et₂₁, Et₃₁, and Et₄₁ are re-calculated in step 20. By means of the prior art, actual measurements of the open, short, load, and thru standard devices were necessary in order to calculate these error coefficients. However, by using formulas 10 and 11 it is possible to calculate new error coefficients Es₁new, Ed₁new, and Er₁new from measurement S₁₁ of the open standard device only. Moreover, by using formulas 7 and 8, it is possible to calculate the new error coefficients El₂₁ new, El₃₁new, El₄₁new, Et₂₁new, Et₃₁new, and Et₄₁new from the new error coefficients Es₁new, Ed₁new, and Er₁new.

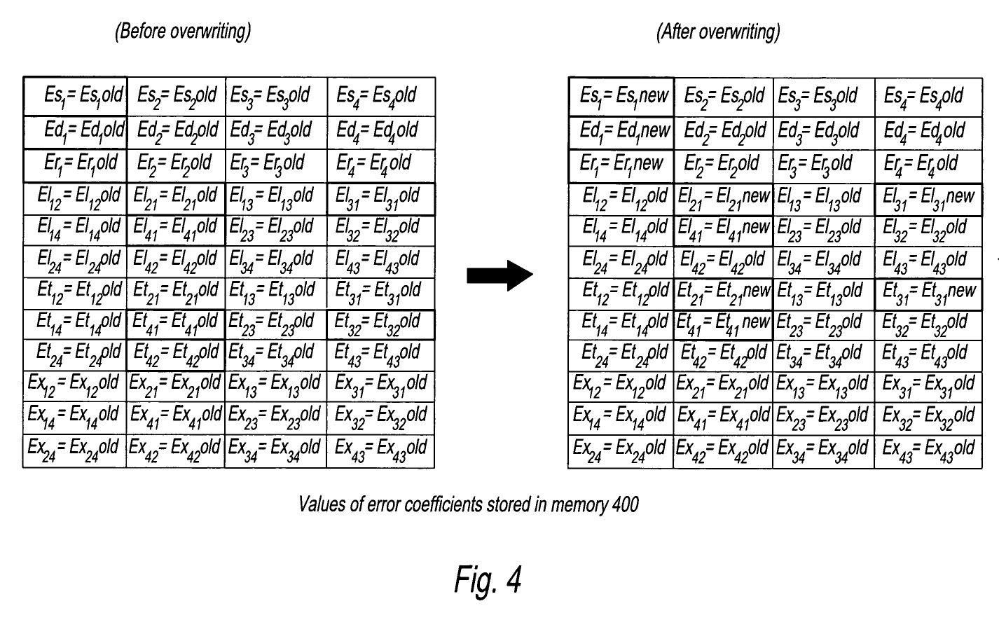

Finally, the error coefficients are written over in step S40. Specifically, the error coefficients newly obtained by re-calculation are written over the error coefficients stored in memory 400 for correction of the measurement values. For instance, when the open standard device is connected to measurement port 1 and only S₁₁ is re-measured, new error coefficient values Es₁new, Ed₁new, Er₁new, El₂₁new, El₃₁new, El₄₁new, Et₂₁new, Et₃₁new, and Et₄₁new are obtained. These new values are written over error coefficients Es₁, Ed₁, Er₁, El₂₁, El₃₁, El₄₁, Et₂₁, Et₃₁, and Et₄₁ stored in memory 400. On the other hand, the error coefficients not written over are left as obtained at the time of calibration (FIG. 4).

Moreover, although not shown in the flow chart in FIG. 2, once step 40 has been performed, network analyzer 10 corrects the measurement values using written-over error coefficients (FIG. 4) while the correction function is active.

By means of the present embodiment, the processing in steps S20 through S40 performed by processor 300 can also be performed by a computer having an external connection to network analyzer 10.

The present embodiment does not describe in detail whether the standard devices used for calibration and re-calibration are the same or different. This is because the present disclosure does not require that the standard devices be identical. Consequently, for instance, it is possible to perform a full N-port calibration of a network analyzer using an electronic calibration kit and then re-calibrate the same network analyzer using a thru standard device of another calibration kit.

In addition, the present embodiment describes a method for re-calibration after a full 4-port calibration of a 4-port network analyzer. However, the present disclosure can be used for re-calibration of a network analyzer having one or more ports. Moreover, it can be used for other calibration methods other than full N-port calibration. In essence, a table for specifying the error coefficients to be calculated such as Table 1 can be created for any calibration method, and re-calibration can be performed by simply calculating only the error coefficients relating to the measured circuit parameters. Moreover, it is possible to find the hypothetical measurement value from an error coefficient that has already been obtained and the theoretical value of the standard device.

What is claimed is:

1. A method for re-calibrating a calibrated network analyzer, said re-calibrating method comprising:
measuring a circuit parameter of a standard device;
specifying the type of error coefficient relating to said measured circuit parameter; and
calculating an error coefficient of said specified type using said measured circuit parameter.

2. The re-calibrating method according to claim 1, further comprising:
of the circuit parameters necessary for said calculation, reproducing a circuit parameter other than said measured circuit parameter using the theoretical value of said circuit parameter and the error coefficient obtained by said calibration.

3. The re-calibrating method according to claim 1, further comprising:
writing the value of the error coefficient obtained by said calculation over the error coefficient obtained by said calibration.

4. A network analyzer, wherein a measurement value is corrected based on an error coefficient obtained by calibration, and also, of the error coefficients obtained by said calibration, an error coefficient that has been re-calculated using the measurement values of a standard device obtained after said calibration.

5. The network analyzer according to claim 4, wherein, of the measurement values necessary for said re-calculation, a measurement value other than the measurement value obtained after said calibration is reproduced using the theoretical value corresponding to said measurement value and the error coefficient obtained by said calibration.

6. The network analyzer according to claim 4, wherein, when the value of the error coefficient obtained by said re-calculation is written over the error coefficient obtained by said calibration, the measurement value is corrected based on said written-over error coefficient.
